(19) United States
(12) Patent Application Publication
(10) Pub. No.: US 2014/0126099 A1
(43) Pub. Date: May 8, 2014

(54) ADJUSTMENT DEVICE FOR A HYDROSTATIC EXPELLER UNIT

(71) Applicant: Robert Bosch GmbH, Stuttgart (DE)

(72) Inventor: Wilfried Eichner, Neubulach (DE)

(73) Assignee: Robert Bosch GmbH, Stuttgart (DE)

(21) Appl. No.: 14/069,007

(22) Filed: Oct. 31, 2013

(30) Foreign Application Priority Data
Nov. 2, 2012 (DE) 10 2012 021 498.7

(51) Int. Cl. H02P 29/00; H05K 13/00

(52) U.S. Cl. CPC H02P 29/0033; H05K 13/00
USPC 361/160; 29/729

(57) ABSTRACT

An adjustment device for a hydrostatic expeller unit includes an electrically actuable adjustment unit and a replaceable ballast unit. The ballast unit has at least one measuring transducer which converts a manipulated variable for the adjustment device into an electrical control signal for the adjustment unit and transmits it to the electrically actuable adjustment unit.

This application claims priority under 35 U.S.C. §119 to patent application no. DE 10 2012 021 498.7 filed on Nov. 2, 2012 in Germany, the disclosure of which is incorporated herein by reference in its entirety.

### BACKGROUND

The present disclosure relates to an adjustment device for a hydrostatic expeller unit.

Adjustment device for hydrostatic expeller units, in particular axial piston machines with a swashplate design are known, for example, from DE 32 13 958 A1. They are used to set the expeller volume of the expeller unit. They have an actuator element, for example a valve, which acts on an adjustment means, for example, an actuating piston, which determines the expeller volume (delivery volume or swept volume) of the expeller unit. The actuating piston acts in turn, for example, on a pivoting body, for example a swashplate, and changes the oblique position thereof. Mechanical or hydraulic adjustment devices which can be actuated and activated mechanically (for example by means of a rotary wheel or Bowden cable), hydraulically (by control pressure) or electrically (by control signal) are customary.

It is desirable to specify an improved adjustment device for a hydrostatic expeller unit which is preferably also suitable for various actuation methods.

### SUMMARY

An adjustment device for a hydrostatic expeller unit having the features of the disclosure is proposed. Advantageous refinements are the subject matter of the dependent claims and of the following description.

Within the scope of the disclosure, an adjustment device for a hydrostatic expeller unit is proposed which comprises an electrically actuable adjustment unit (in particular having an analog and/or digital current input and/or voltage input and/or frequency input) and a ballast unit (in particular having a corresponding analog and/or digital current output, voltage output and/or frequency output), wherein the ballast unit has a measuring transducer which converts a manipulated variable into an electrical control signal and transmits it to the electrically actuable adjustment unit. The adjustment device can also contain a closed-loop controller (that is to say with actual value feedback).

All the conventional actuation methods can be advantageously implemented by selecting a suitable measuring transducer. The input signal of a measuring transducer is a manipulated variable as a physically measurable variable, wherein, in particular, pressure, rotational angle, travel, force, electrical voltage and electrical current are suitable here. For example, when a pressure measuring transducer is used the adjustment unit can be controlled by means of control pressure, and when a travel measuring transducer is used control can be performed by means of mechanical changes in the length (for example Bowden cable) etc. The adjustment unit itself does not have to be changed here. The disclosure therefore increases the proportion of identical parts in adjustment devices, which simplifies the manufacture, maintenance etc. Adjustment devices in the field can be quickly adapted to changed conditions or new machines. This leads to a considerable saving in cost.

The electrically actuable adjustment unit preferably has at least one input for the electrical control signal, which input is configured to receive an analog and/or digital signal. What are referred to as standardized analog unit signals, for example current signals 0 . . . 20 mA or 4 . . . 20 mA or a voltage signal 0 . . . 10 V or 2 . . . 10 V or a frequency signal are particularly suitable as an analog signal. Standardized digital signals such as, for example, field bus signals, (for example CAN) are particularly suitable as digital signals. In a corresponding way, the ballast unit expediently has a correspondingly configured output.

Since essentially mechanical-hydraulic closed-loop and adjustment devices are replaced by electronic ballast units and an electrically actuable adjustment unit, a wide variety of requirements can be met and implemented flexibly with a base unit (composed of the electrically actuable adjustment unit and preferably a hydrostatic expeller unit) and a corresponding ballast unit. In particular, mechanical, hydraulic, pneumatic and electronic actuation systems can be implemented with the same adjustment unit. The range of variants is reduced. The disclosure provides a kit for making available an adjustment device from an electrically actuable adjustment unit and a number of ballast units of different types, wherein the types differ in the kind of measurable manipulated variables.

Further advantages and refinements of the disclosure can be found in the description and the appended drawing.

Of course, the features which are mentioned above and which will be explained below can be used not only in the respectively specified combination but also in other combinations or alone without departing from the scope of the present disclosure.

### BRIEF DESCRIPTION OF THE DRAWING

The disclosure is illustrated schematically in the drawing by means of exemplary embodiments and will be described in detail below with reference to the drawing.

FIG. 1 is a schematic view of an arrangement composed of a hydrostatic expeller unit and an adjustment device according to a preferred embodiment of the disclosure.

### DETAILED DESCRIPTION

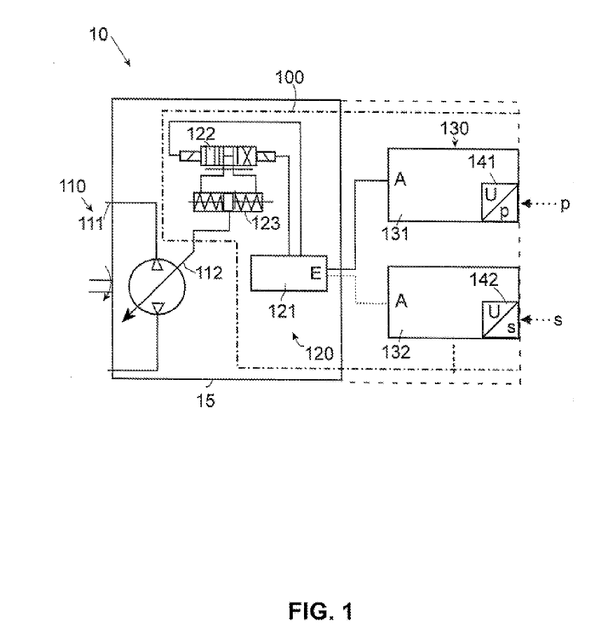

FIG. 1 illustrates an arrangement 10 composed of a hydrostatic expeller unit 110 and an adjustment device 100 according to a preferred embodiment of the disclosure. The hydrostatic expeller unit 110 has working line connections 111 and a pivoting body 112 which is embodied, for example, as a swashplate (in an axial piston machine).

The adjustment device 100 has an adjustment unit 120 which is installed on the hydrostatic expeller unit 110 and forms therewith a hydrostatic base unit 15. The adjustment device 100 also has a ballast unit 130, wherein two exemplary alternative ballast units 131, 132 of different types are illustrated in FIG. 1.

The adjustment unit 120 has a control device 121 which is connected to a valve 122 as an actuator element. The valve 122 is connected to an actuating piston 123 as an adjustment means, which actuating piston 123 acts on the swashplate 112 in order as a result to change an expeller volume of the hydrostatic expeller unit 110. The control device 121 is electrically connected to actuators (for example electromagnets) of the valve 122 and configured to actuate the valve 122. The control device 121 has one or more inputs E for inputting an electrical control signal, for example an analog current or voltage signal or a digital signal (PWM signal, field bus signal, for example CAN, etc.) which predefines a setpoint value for a pivoting angle of the swashplate 112.

The ballast unit 131 of a first type (“pressure ballast unit”) has a pressure measuring transducer 141 which generates an electrical control signal for the control device 121 or the adjustment unit 120 in accordance with a control pressure p as a manipulated variable of a first type. The control signal is output to an output A of the ballast unit 131.

The alternative ballast unit 132 of a second type (“travel ballast unit”) has a travel measuring transducer 142 which generates an electrical control signal for the control device 121 or the adjustment unit 120 in accordance with a change in length s as a manipulated variable of a second type. The control signal is output to an output A of the ballast unit 132.

In this way, the hydrostatic base unit 15 can be configured for different actuation methods (for example electrical, mechanical, pneumatic hydraulic etc.) merely by exchanging the ballast unit 130.

What is claimed is:

1. An adjustment device for a hydrostatic expeller unit, comprising:
an electrically actuable adjustment unit; and
a ballast unit having at least one measuring transducer, the ballast unit being configured to convert a manipulated variable for the adjustment device into an electrical control signal for the adjustment unit and to transmit it to the electrically actuable adjustment unit.

2. The adjustment device according to claim 1, wherein the electrically actuable adjustment unit has at least one input for the electrical control signal, the input being configured to receive one or more of an analog signal and a digital signal.

3. The adjustment device according to claim 1, wherein the ballast unit has at least one output for the electrical control signal, the output being configured to output one or more of an analog signal and a digital signal.

4. The adjustment device according to claim 1, wherein the at least one measuring transducer is configured as a pressure measuring transducer, a travel measuring transducer, a voltage measuring transducer, a current measuring transducer, a rotational angle measuring transducer, or a force measuring transducer.

5. A hydrostatic arrangement, comprising:
an adjustable hydrostatic expeller unit; and
an adjustment device including:
an electrically actuable adjustment unit; and
a ballast unit having at least one measuring transducer, the ballast unit being configured to convert a manipulated variable for the adjustment device into an electrical control signal for the adjustment unit and to transmit it to the electrically actuable adjustment unit.

6. The hydrostatic arrangement according to claim 5, wherein the hydrostatic expeller unit and the electrically actuable adjustment unit are combined structurally to form a hydrostatic base unit.

7. The hydrostatic arrangement according to claim 5, wherein the electrically actuable adjustment unit has an actuator element configured to act on an adjustment mechanism to determine an expeller volume of the hydrostatic expeller unit.

8. The hydrostatic arrangement according to claim 7, wherein the actuator element has an electrically actuable directional control valve.

9. A kit for producing an adjustment device, comprising:
an electrically actuable adjustment unit; and
at least two ballast units of different types, each ballast unit having at least one measuring transducer,
wherein a ballast unit of a first type is configured to convert a manipulated variable of a first type for the adjustment device into an electrical control signal for the adjustment unit and to transmit it to the electrically actuable adjustment unit, and
wherein a ballast unit of a second type is configured to convert a manipulated variable of a second type for the adjustment device into an electrical control signal for the adjustment unit and to transmit it to the electrically actuable adjustment unit.
